(19) United States
(12) Patent Application Publication
(10) Pub. No.: US 2017/0090229 A1
(43) Pub. Date: Mar. 30, 2017

(54) SEMICONDUCTOR DEVICE, DISPLAY DEVICE AND METHOD FOR MANUFACTURING SEMICONDUCTOR DEVICE

(71) Applicant: Sharp Kabushiki Kaisha, Osaka (JP)

(72) Inventors: Hajime IMAI, Osaka (JP); Tohru DAITOH, Osaka (JP); Hisao OCHI, Osaka (JP); Tetsuo FUJITA, Osaka (JP); Hideki KITAGAWA, Osaka (JP); Tetsuo KIKUCHI, Osaka (JP); Masahiko SUZUKI, Osaka (JP); Shingo KAWASHIMA, Osaka (JP)

(73) Assignee: Sharp Kabushiki Kaisha, Osaka (JP)

(21) Appl. No.: 15/316,091

(22) PCT Filed: May 29, 2015
(86) PCT No.: PCT/JP2015/065527

§ 371 Date: Dec. 2, 2016

(30) Foreign Application Priority Data
Jun. 6, 2014 (JP) 2014-117478

(51) Int. Cl. G02F 1/1368; G02F 1/1362; G02F 1/1333

(52) U.S. Cl. CPC G02F 1/1368; G02F 1/133345; G02F 1/136209; G02F 1/136227; G02F 1/136286; G02F 2201/123; G02F 2202/10; H01L 27/1225

(57) ABSTRACT

The semiconductor device of the present invention is provided with: source wiring lines that are formed on a substrate; light-shielding members that are in the same layer as the source wiring lines; a source insulating film that covers the source wiring lines and the like; holes that penetrate the source insulating film; channel region that are formed of an oxide semiconductor film that is formed on the source insulating film so as to overlap the light-shielding members; source electrode portions that are formed of the oxide semiconductor film, the resistance of which has been decreased, and that are connected to the source wiring lines via the holes; drain electrode portions that are formed of the oxide semiconductor film, the resistance of which has been decreased, and that oppose the source electrode portions with the channel region being interposed therebetween; gate insulating films that are formed on the channel region; and gate electrodes that are formed on the gate insulating films so as to overlap the channel region.

### TECHNICAL FIELD

The present invention relates to a semiconductor device, a display device, and a method of manufacturing a semiconductor device.

### BACKGROUND ART

TFT array substrates used in liquid crystal display devices and the like include thin-film transistors (hereinafter, “TFT”) as switching elements in each pixel. Conventionally, amorphous silicon, polycrystalline silicon, and the like were used for the active layer of TFTs, but in recent years, oxide semiconductors such as zinc oxide have been in use due to high electron mobility, a relatively simple film-forming process, and the like.

Patent Document 1 discloses a top gate TFT that uses as the active layer an oxide semiconductor such as an oxide containing indium (In), gallium (Ga), and zinc (Zn). Specifically, Patent Document 1 discloses a configuration in which an oxide semiconductor film is formed on a glass substrate, and a gate insulating film and a gate electrode are layered in this order on the oxide semiconductor film.

### RELATED ART DOCUMENT

### Patent Document

Patent Document 1: Japanese Patent Application Laid-Open Publication No. 2012-33836

### Problems to be Solved by the Invention

In conventional top gate TFTs, when light is radiated towards the glass substrate from a backlight device or the like, the light passes through the glass substrate and hits the oxide semiconductor film. When light hits the oxide semiconductor film, this results in the problem of reduced performance for the oxide semiconductor film.

### SUMMARY OF THE INVENTION

An object of the present invention is to provide a top gate semiconductor device or the like in which degradation of the oxide semiconductor film due to light is mitigated.

### Means for Solving the Problems

A semiconductor device of the present invention includes: a substrate; a source wiring line formed on the substrate; a light-shielding member formed on the substrate in a same layer as the source wiring line so as to be separated from or connected to the source wiring line; a source insulating film formed on the substrate so as to cover the source wiring line and the light-shielding member; a hole formed through the source insulating film in a thickness direction so as to expose a portion of the source wiring line; a channel region made of an oxide semiconductor film formed on the source insulating film so as to overlap the light-shielding member; a source electrode portion formed by reducing a resistance of a same type of oxide semiconductor film as used in the channel region, the source electrode portion being formed on the source insulating film such that one end of the source electrode portion is connected to the source wiring line through the hole and another end of the source electrode portion is connected to the channel region; a drain electrode portion formed by reducing a resistance of the same type of oxide semiconductor film as used in the channel region, the drain electrode portion being formed on the source insulating film so as to oppose the source electrode portion with the channel region therebetween, the drain electrode portion being connected to the channel region; a gate insulating film formed over the channel region so as to overlap the channel region; and a gate electrode formed on the gate insulating film so as to overlap the channel region.

The semiconductor device of the present invention is of the top gate type as described above, and the channel region made of the oxide semiconductor film is provided so as to overlap the light-shielding member. Thus, when light is supplied from the substrate side, the light-shielding member blocks the light such that no light hits the channel region, thereby mitigating degradation of the oxide semiconductor film constituting the channel region.

In the semiconductor device, it is preferable that the source wiring line and the light-shielding member be made of a same conductive material. If the source wiring lines and the light-shielding members are made of the same conductive material, it is possible to manufacture the source wiring lines and the light-shielding members in the same manufacturing step, which enables excellent productivity.

In the semiconductor device, it is preferable that the channel region be formed so as not to protrude from edges of the light-shielding member. If the channel region is formed so as not to protrude from the edges of the light-shielding members, the light-shielding members can more reliably protect the channel region from light.

It is preferable that the semiconductor device further include an interlayer insulating film formed on the source insulating film so as to cover the source electrode portion and the drain electrode portion.

In the semiconductor device, it is preferable that the interlayer insulating film contain as a primary component silicon nitride, and that hydrogen contained in the interlayer insulating film reduce the resistance of portions of the oxide semiconductor film corresponding to the source electrode portion and the drain electrode portion. If the interlayer insulating film is configured in this manner, it is possible to reliably reduce the resistance of portions of the oxide semiconductor film adjacent to the interlayer insulating film.

In the semiconductor device, it is preferable that the oxide semiconductor film contain indium (In), gallium (Ga), zinc (Zn), and oxygen (O).

The semiconductor device may further include: a pixel electrode connected to the drain electrode portion, wherein the semiconductor device constitutes a pixel transistor in a display region.

The semiconductor device may constitute a driver circuit transistor formed in a peripheral region around a display region.

A display device of the present invention includes: the semiconductor device; an opposite substrate disposed opposite the semiconductor device; and a liquid crystal layer interposed between the semiconductor device and the opposite substrate.

The display device may include a backlight device that supplies light towards the semiconductor device.

A method of manufacturing a semiconductor device of the present invention includes: forming a conductive film on a substrate; patterning the conductive film to form, on the substrate, a source wiring line and a light-shielding member in a same layer as the source wiring line so as to be separated from or connected to the source wiring line; forming a source insulating film on the substrate so as to cover the source wiring line and the light-shielding member; forming a hole through the source insulating film in a thickness direction thereof so as to expose a portion of the source wiring line; forming an oxide semiconductor film on the source insulating film so as to overlap the light-shielding member while being connected to the source wiring line through the hole; forming a gate insulating film on a channel region portion of the oxide semiconductor film so as to cover the channel region portion that overlaps the light-shielding member; forming a gate electrode on the gate insulating film so as to overlap the channel region portion; and forming an interlayer insulating film on the source insulating film so as to cover portions of the oxide semiconductor film that are not covered by the gate insulating film. The method of manufacturing semiconductor device of the present embodiment is provided with such steps, making it possible to provide a semiconductor device in which degradation of the oxide semiconductor film due to light is mitigated.

In the method of manufacturing a semiconductor device, it is preferable that the oxide semiconductor film contain indium (In), gallium (Ga), zinc (Zn), and oxygen (O).

In the method of manufacturing a semiconductor device, it is preferable that the interlayer insulating film contain a silicon nitride as a primary component and be formed by plasma-enhanced chemical vapor deposition. If the interlayer insulating film is configured in this manner and is formed by plasma-enhanced chemical vapor deposition, it is possible to reliably reduce the resistance of portions of the oxide semiconductor film adjacent to the interlayer insulating film.

### Effects of the Invention

According to the present invention it is possible to provide a top gate semiconductor device or the like in which degradation of the oxide semiconductor film due to light is mitigated.

### BRIEF DESCRIPTION OF THE DRAWINGS

FIG. 1 is a descriptive drawing that schematically shows a cross-sectional configuration of a liquid crystal display device.

FIG. 2 is a plan view that schematically shows the configuration of a TFT on a TFT array substrate of Embodiment 1.

FIG. 3 is a cross-sectional view along the line A-A of FIG. 1.

FIG. 4 is a plan view of a substrate that schematically shows a state in which a source wiring line and a light-shielding member are formed on a transparent substrate.

FIG. 5 is a cross-sectional view along the line B-B of FIG. 4.

FIG. 6 is a plan view of a substrate that schematically shows a state in which a source insulating film is formed on the transparent substrate so as to cover the source wiring line and the light-shielding member.

FIG. 7 is a cross-sectional view along the line C-C of FIG. 6.

FIG. 8 is a cross-sectional view of a substrate that schematically shows a state in which an oxide semiconductor film is formed on the source insulating film.

FIG. 9 is a cross-sectional view of a substrate that schematically shows a state in which a gate insulating film and a metal layer are formed on the oxide semiconductor film.

FIG. 10 is a plan view of a substrate that schematically shows a state in which a gate electrode and a gate wiring line have been formed by patterning.

FIG. 11 is a cross-sectional view along the line D-D of FIG. 10.

FIG. 12 is a cross-sectional view of a substrate that schematically shows a state in which the gate insulating film has been patterned.

FIG. 13 is a plan view of a substrate that schematically shows a state in which the oxide semiconductor film has been patterned.

FIG. 14 is a cross-sectional view along the line E-E of FIG. 13.

FIG. 15 is a cross-sectional view of a substrate that schematically shows a state in which a first interlayer insulating film and an organic insulating film are formed so as to cover the oxide semiconductor film and the like.

FIG. 16 is a plan view of a substrate that schematically shows a state in which a common electrode has been formed.

FIG. 17 is a cross-sectional view along the line F-F of FIG. 16.

FIG. 18 is a plan view of a substrate that schematically shows a state in which a second interlayer insulating film has been formed.

FIG. 19 is a cross-sectional view along the line G-G of FIG. 18.

FIG. 20 is a plan view that schematically shows the configuration of a TFT on a TFT array substrate of Embodiment 2.

FIG. 21 is a cross-sectional view along the line H-H of FIG. 20.

FIG. 22 is a plan view that schematically shows the configuration of a TFT on a TFT array substrate of Embodiment 3.

FIG. 23 is a cross-sectional view along the line I-I of FIG. 22.

### DETAILED DESCRIPTION OF EMBODIMENTS

### Embodiment 1

### Liquid Crystal Display Device

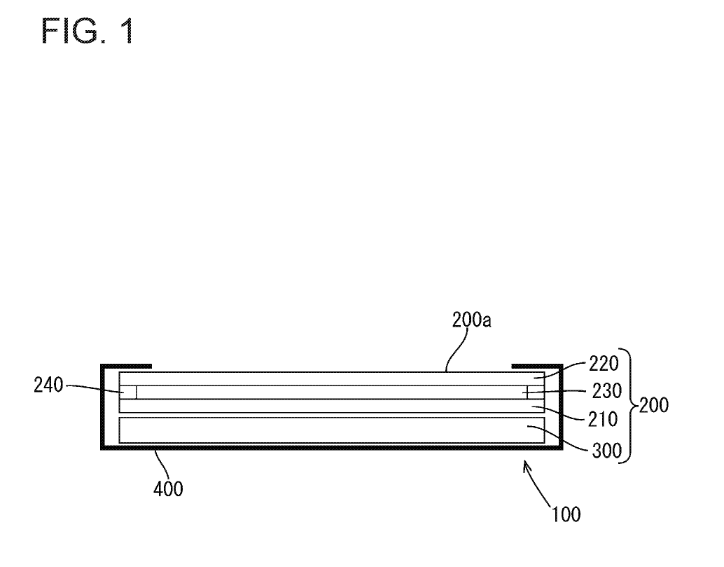

Embodiment 1 of the present invention will be explained below with reference to FIGS. 1 to 19. In the present embodiment, a TFT array substrate (an example of a semiconductor device) used in a liquid crystal display device (an example of a display device) provided with a backlight device will be described. FIG. 1 is a descriptive drawing that schematically shows a cross-sectional configuration of a liquid crystal display device 100.

The liquid crystal display device 100 includes a liquid crystal display panel 200 that displays an image on a display surface 200a; a backlight device 300 that supplies light to the liquid crystal display panel 200; a case 400 that houses the liquid crystal display panel 200, the backlight device 300; and the like. The liquid crystal display panel 200 has a configuration in which a pair of glass substrates 210 and 220 are bonded to each other via a frame-shaped sealing material 240, with a prescribed gap therebetween, while having a liquid crystal layer 230 sealed between the two glass substrates 210 and 220. The liquid crystal display panel 200 of the present embodiment operates in fringe field switching (FFS) mode.

One glass substrate 210 is a TFT array substrate 210 (an example of a semiconductor device) in which a plurality of TFTs that are switching elements and a plurality of pixel electrodes electrically connected thereto are arranged in a matrix on a transparent glass substrate (transparent substrate). The TFT array substrate 210 is provided with source wiring lines and gate wiring lines that delineate the TFTs and the like. Furthermore, the TFT array substrate 210 is provided with a common electrode that opposes the pixel electrodes, and alignment films and the like formed so as to cover the pixel electrodes and the like. As will be described later, the TFTs in the TFT array substrate 210 are of the top gate type, and an oxide semiconductor is used therein as the active layer.

The other glass substrate 220 is an opposite substrate 220 that is disposed opposite the TFT array substrate 210, and that has a configuration in which an alignment film and color filters including colored portions of red (R), green (G), blue (B), and the like in a prescribed arrangement are disposed on a transparent glass substrate (transparent substrate). Polarizing plates (not shown) are respectively provided on outer sides of the two substrates 210 and 220.

The backlight device 300 has light emitting diodes (LEDs) as the light source and radiates light towards the liquid crystal display panel 200. As shown in FIG. 1, the backlight device 300 is disposed on the TFT array substrate 210 side of the liquid crystal display panel 200 and radiates light towards the TFT array substrate 210. The liquid crystal display panel 200 uses the light supplied from the backlight device 300 to display images in the display surface 200a.

The liquid crystal display device 100 according to the present embodiment is used in various electronic devices such as mobile phones (including smartphones and the like), laptop computers, tablet devices, portable information terminals (including electronic books, PDAs, etc.), digital photo frames, portable gaming devices, and electronic ink paper.

(TFT Array Substrate)

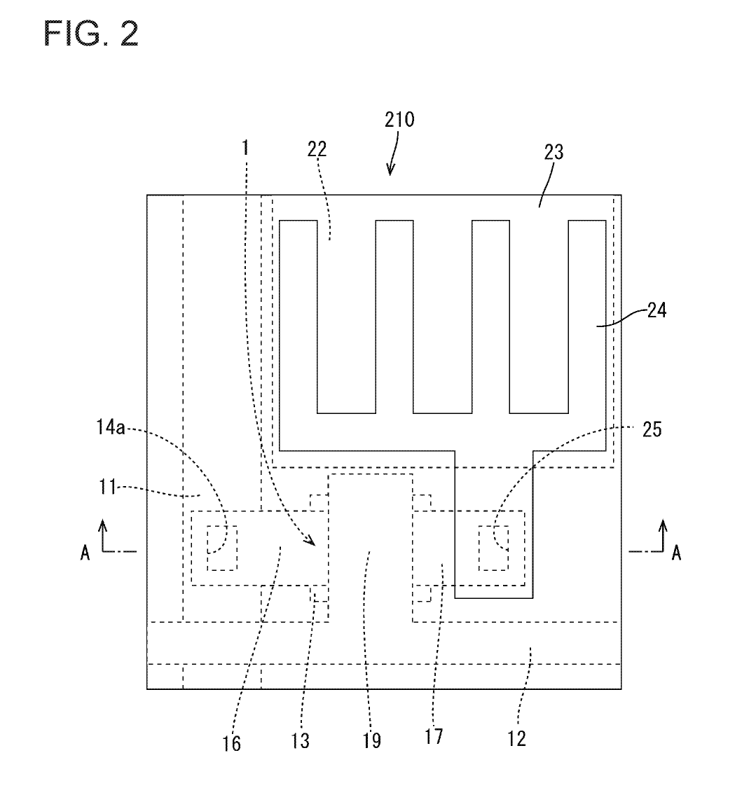

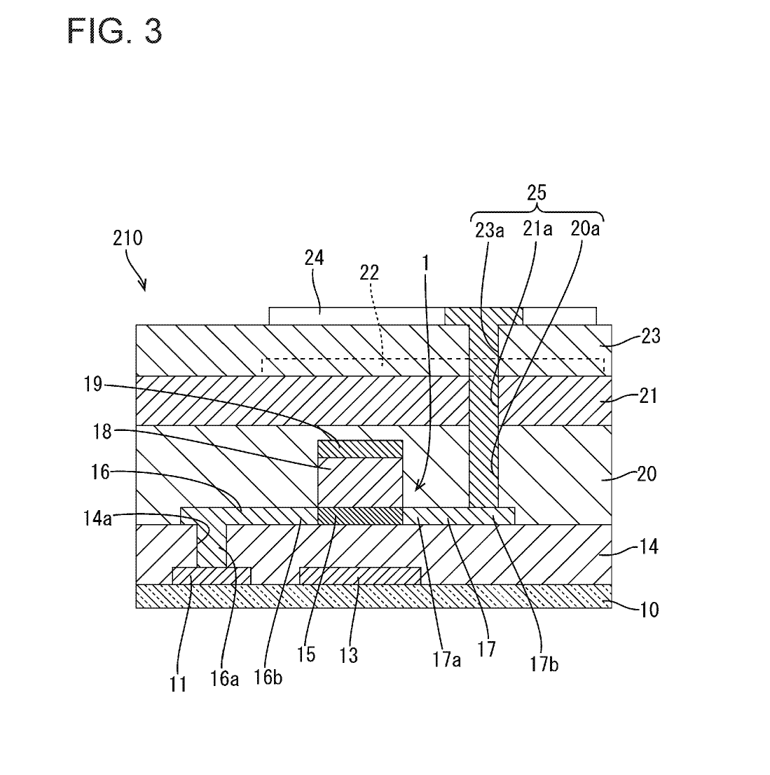

Next, the TFT array substrate 210 will be described in detail with reference to FIGS. 2 to 19. FIG. 2 is a plan view that schematically shows the configuration of a TFT 1 on a TFT array substrate 210 of Embodiment 1, and FIG. 3 is a cross-sectional view along the line A-A of FIG. 2. The TFT array substrate 210 of the present embodiment includes top gate TFTs 1. These TFTs 1 are pixel transistors formed in the pixel area (display region).

The TFT array substrate 210 includes a transparent substrate 10, source wiring lines 11, gate wiring lines 12, light-shielding members 13, a source insulating film 14, channel region 15, source electrode portions 16, drain electrode portions 17, gate insulating films 18, gate electrodes 19, a first interlayer insulating film 20, an organic insulating film 21, a common electrode 22, a second interlayer insulating film 23, pixel electrodes 24, and the like. The TFT array substrate 210 further includes other components such as an alignment film but these are omitted from description for ease of explanation.

The transparent substrate 10 is made of a glass plate as described above. Various substrates can be used for the transparent substrate 10, which is not limited to being made of glass. A single-crystal semiconductor substrate, an oxide single-crystal substrate, a metal substrate, a glass substrate, a quartz substrate, a resin substrate, or the like can be used for the transparent substrate 10, for example. If a conductive substrate such as a single-crystal semiconductor substrate or a metal substrate is used, for example, then it is preferable that an insulating film or the like be provided thereon.

The source wiring lines 11 are formed into a linear pattern having a prescribed width, and are formed directly on the transparent substrate 10. The source wiring lines 11 are made of a conductive film and have a single layer or multiple layers. The source wiring lines 11 are made by layering titanium (Ti), copper (Cu), and titanium (Ti) films in this order on the transparent substrate 10, for example.

The light-shielding members 13 are provided to protect the channel region 15 of the TFT 1 from being exposed to light, and, similar to the source wiring lines 11, are formed directly on the transparent substrate 10. The light-shielding member 13 has a quadrilateral shape in a plan view and is arranged on the transparent substrate 10 so as to overlap the channel region 15. The light-shielding member 13 is formed to be larger than the channel region 15 so as to be able to protect the entire channel region 15. In addition, the light-shielding member 13 is formed of the same conductive material (conductive film) as the source wiring lines 11. As will be described later, the light-shielding members 13 are produced in the same manufacturing step as the source wiring lines 11.

As shown in FIGS. 2 and 3, the light-shielding member 13 of the present embodiment is formed on the transparent substrate 10 in the same layer as the source wiring lines 11 while being positioned away from the source wiring lines 11.

The source insulating film 14 is formed on the transparent substrate 10 so as to cover the source wiring lines 11 and the light-shielding members 13. The source insulating film 14 is made of a silicon oxide film (SiO₂), for example.

The source insulating film 14 has formed therein holes (contact holes) 14a. The holes 14a are provided in positions that overlap the source wiring lines 11 in a plan view, and are formed through the source insulating film 14 in the thickness direction thereof so as to expose a portion of the source wiring lines 11.

The channel region 15 is made of an oxide semiconductor film containing indium (In), gallium (Ga), zinc (Zn), and oxygen (O). The channel region 15 is formed in a quadrilateral shape on the source insulating film 14 so as to overlap the light-shielding members 13 in a plan view. The channel region 15 is formed so as not to protrude from the edges of the light-shielding members 13. The channel region 15 is a portion arranged between the source electrode portion 16 and the drain electrode portion 17, and is sandwiched therebetween. The channel region 15 is connected integrally with the source electrode portion 16 and the drain electrode portion 17.

The source electrode portion 16 is made of a similar oxide semiconductor film to the channel region 15 (that is, an oxide semiconductor film containing indium (In), gallium (Ga), zinc (Zn), and oxygen (O)), but with a reduced resistance so as to be conductive. In other words, the source electrode portion 16 is formed using the same material (oxide semiconductor film) as the channel region 15. The source electrode portion 16 is formed in a belt shape in a plan view along the surface of the source insulating film 14. Also, one end 16a (towards the source wiring line 11) extends in the thickness direction of the source insulating film 14 along the taper of the hole 14a. As shown in FIG. 3, the source electrode portion 16 is formed on the source insulating film 14 such that one end 16a thereof is connected to the source wiring line 11 through the hole 14a, and the other end 16b thereof is connected to the channel region 15.

Similar to the source electrode portion 16, the drain electrode portion 17 is made of a similar oxide semiconductor film to the channel region 15 (that is, an oxide semiconductor film containing indium (In), gallium (Ga), zinc (Zn), and oxygen (O)), but with a reduced resistance so as to be conductive. In other words, the drain electrode portion 17 is formed using the same material (oxide semiconductor film) as the channel region 15. The drain electrode portion 17 is formed on the source insulating film 14 so as to oppose the source electrode portion 16 across the channel region 15. One end 17a (towards the channel region 15) of the drain electrode portion 17 is connected to the channel region 15 and the other end 17b thereof is connected to the pixel electrode 24.

The gate insulating film 18 is formed over the channel region 15 so as to overlap the channel region 15. As shown in FIG. 3, the gate insulating film 18 is sandwiched between the channel region 15 and the gate electrode 19. The gate insulating film 18 is formed by layering a silicon oxide film (SiO₂) and a silicon nitride film (SiN_{X}) in this order on the channel region 15. The gate insulating film 18 is also formed in portions that overlap the gate wiring lines 12 in a plan view.

As shown in FIG. 2, the gate wiring lines 12 are formed into a linear pattern having a prescribed width, and are formed on the gate insulating films 18. The gate wiring lines 12 are made of a conductive film and have a single layer or multiple layers. The gate wiring lines 12 are made by layering titanium (Ti) and copper (Cu) films in this order on the gate insulating film 18, for example. The gate wiring lines 12 are provided so as to be perpendicular to the source wiring lines 11 in a plan view.

The gate electrode 19 is formed on the gate insulating film 18 so as to overlap the channel region 15. The gate electrode 19 is made of a similar conductive film to the gate wiring line 12 and is connected integrally to the gate wiring line 12. As shown in FIG. 2, the gate electrode 19 is formed so as to jut out from the gate wiring line 12, and the source electrode portion 16 and the drain electrode portion 17 are arranged so as to oppose each other with the gate electrode 19 therebetween.

The first interlayer insulating film 20 is formed on the source insulating film 14 so as to cover the source electrode portion 16 and the drain electrode portion 17. The first interlayer insulating film 20 is made of a silicon nitride film (SiN_{X}), for example. The first interlayer insulating film 20 made of a silicon nitride film is formed by plasma-enhanced chemical vapor deposition (PECVD), which has excellent productivity characteristics, for example. A certain amount of hydrogen is contained in the silicon nitride film. A large amount of hydrogen remains especially in silicon nitride films formed by plasma-enhanced chemical vapor deposition. The hydrogen in the silicon nitride film moves towards the source electrode portion 16 and the drain electrode portion 17, which are in contact with the first interlayer insulating film 20. The source electrode portion 16 and the drain electrode portion 17 are formed of a similar oxide semiconductor film to the channel region 15 but with a reduced resistance as a result of reacting with the hydrogen contained in the first interlayer insulating film 20.

The organic insulating film 21 is made of a photosensitive resin or the like, and is formed on the first interlayer insulating film 20 by the spin coating method or the like so as to cover the first interlayer insulating film 20. The common electrode 22 is additionally formed on the organic insulating film 21. The common electrode 22 is made of a transparent conductive material such as indium tin oxide (ITO) or indium zinc oxide (IZO), and is formed by sputtering or the like.

The second interlayer insulating film 23 is formed on the common electrode 22 and the organic insulating film 21 so as to cover the common electrode 22. Similar to the first interlayer insulating film 20, the second interlayer insulating film 23 is made of a silicon nitride (SiN_{X}) by plasma-enhanced chemical vapor deposition or the like, for example.

The pixel electrodes 24 are made of a transparent conductive material such as indium tin oxide (ITO) or indium zinc oxide (IZO), and are formed by sputtering or the like on the second interlayer insulating film 23. The pixel electrode 24 is connected to the drain electrode portion 17 through the hole 25 formed through the first interlayer insulating film 20, the organic insulating film 21, and the second interlayer insulating film 23 in the thickness direction thereof. The first interlayer insulating film 20, the organic insulating film 21, and the second interlayer insulating film 23 respectively have penetrating holes 20a, 21a, and 23a (through holes) formed therethrough.

By the TFT array substrate 210 of the present embodiment being provided with the configuration above, it is possible to mitigate degradation (photodegradation) of the channel region 15 by light from the backlight device 300. The transparent substrate 10 side of the channel region 15 of the TFT 1 is covered by the light-shielding member 13. Thus, even when light is radiated from the backlight device 300 towards the rear surface (TFT array substrate 210) of the liquid crystal display panel 200, the light-shielding member 13 blocks the light, blocking light from hitting the channel region 15.

In the TFT array substrate 210 of the present embodiment, the light-shielding members 13 are made of the same conductive material (source metal) as the source wiring lines 11, and therefore, the light-shielding members 13 can be produced in the same manufacturing step as the source wiring lines 11. Thus, the TFT array substrate 210 of the present embodiment can be provided with the light-shielding members 13 in prescribed positions without complicating the manufacturing process.

In the TFT array substrate 210 of the present embodiment, the channel region 15 is formed so as not to protrude from the edges of the light-shielding members 13 in a plan view. Thus, the channel region 15 can be protected more reliably from exposure to light by not protruding outside of the light-shielding members 13 in a plan view.

As described above, in the TFT array substrates 210 of the present embodiment, the TFTs 1 are of the top gate type, the source wiring lines 11 are formed on the transparent substrate 10, and the gate electrodes 19 are formed over the channel region 15 made of the oxide semiconductor film formed over the source insulating film 14, with the gate insulating film 18 being interposed between the gate electrode 19 and the channel region 15. The source electrode portion 16 and the drain electrode portion 17 are formed on the source insulating film 14 so as to oppose each other across the channel region 15. In the TFT array substrate 210 having such a configuration, the gate electrode 19 and the source electrode portion 16 do not overlap in a plan view, which mitigates the occurrence of parasitic capacitance. As a result, increases in power consumption when writing display data, dulling of signals, and the like are mitigated.

In the TFT array substrate 210 of the present embodiment, the source electrode portion 16 and the drain electrode portion 17 are both formed by reducing the resistance (increasing the conductivity) of the same oxide semiconductor film that forms the channel region 15. The source electrode portion 16 and the drain electrode portion 17 are in direct contact with the first interlayer insulating film 20, and thus, the hydrogen contained in the first interlayer insulating film 20 can react with the oxide semiconductor film forming the source electrode portion 16 and the drain electrode portion 17, which reduces the resistance of the oxide semiconductor film. The oxide semiconductor film constituting the channel region 15 is covered by the gate insulating film 18, which prevents reaction with the hydrogen in the first interlayer insulating film 20.

The TFT array substrate 210 of the present embodiment can be taken apart and the shape of the patterns and the like of the TFT array substrate 210 can be observed by an optical microscope, a scanning transmission electron microscope (STEM), a scanning electron microscope (SEM), or the like.

(Method of Manufacturing TFT Array Substrate)

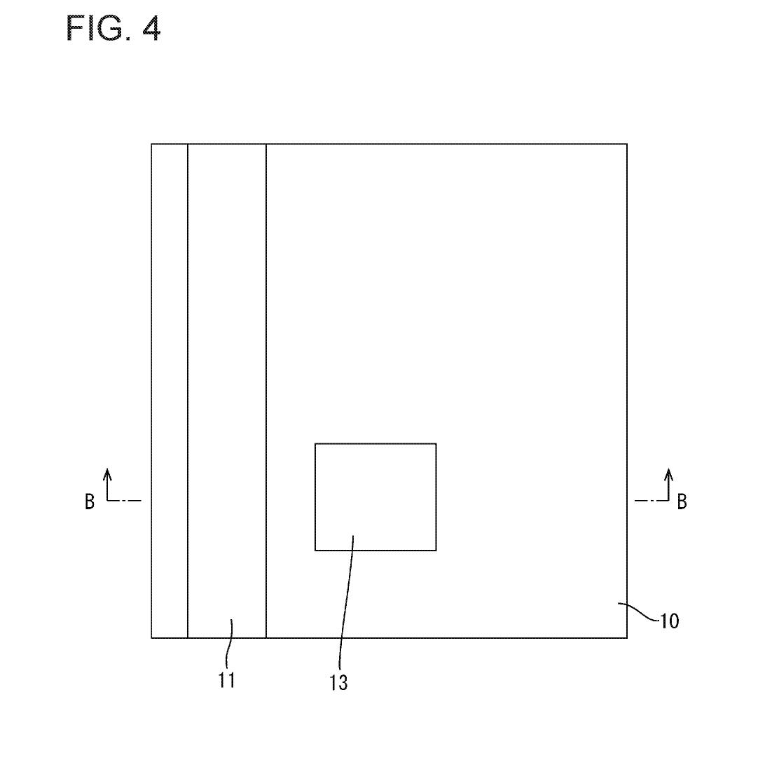

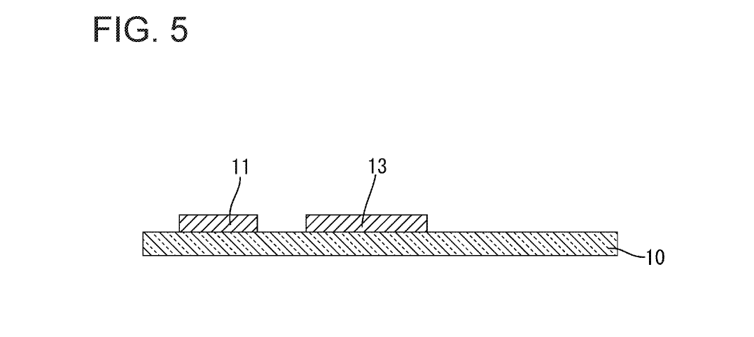

Next, the method of manufacturing the TFT array substrate 210 of Embodiment 1 will be described in detail. FIG. 4 is a plan view of a substrate that schematically shows a state in which the source wiring line 11 and the light-shielding member 13 are formed on the transparent substrate 10, and FIG. 5 is a cross-sectional view along the line B-B of FIG. 4. As shown in FIGS. 4 and 5, the source wiring line 11 and the light-shielding member 13 are formed on the transparent substrate 10. By patterning a metal layer (source metal layer), which has been formed over the entire transparent substrate 10 by sputtering or the like, into a desired shape by photolithography or the like, the source wiring lines 11 and the light-shielding members 13 are formed. Specifically, a resist having a prescribed pattern is formed by a mask process on the metal layer, and then the metal layer is etched (by wet etching, for example), causing the source wiring lines 11 and the light-shielding members 13 to be formed as the pattern. The resist is removed as appropriate. In this manner, the light-shielding members 13 are produced of the same conductive material (metal layer) and in the same manufacturing step as the source wiring lines 11.

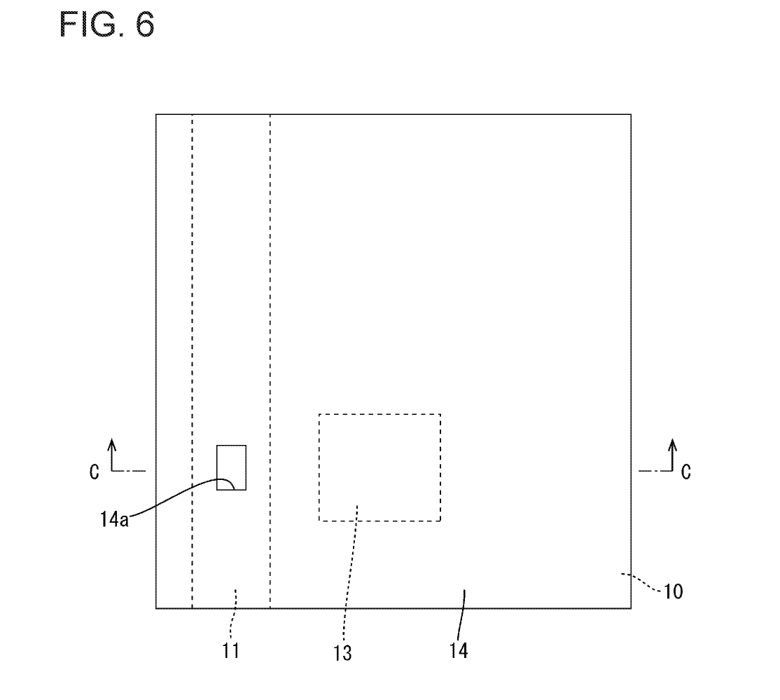

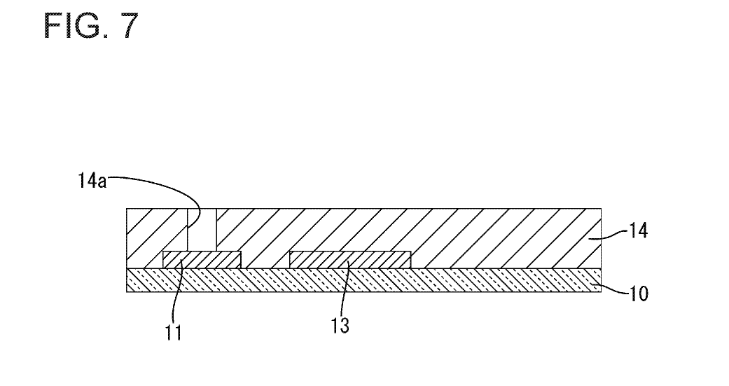

FIG. 6 is a plan view of a substrate that schematically shows a state in which a source insulating film 14 is formed on the transparent substrate 10 so as to cover the source wiring line 11 and the light-shielding member 13, and FIG. 7 is a cross-sectional view along the line C-C of FIG. 6. As shown in FIGS. 6 and 7, after the source wiring lines 11 and the light-shielding members 13 are formed, the source insulating film 14 is formed over the entire transparent substrate 10 so as to cover the source wiring lines 11 and the light-shielding members 13. The source insulating film 14 is made of a silicon oxide film (SiO₂), for example, and is formed by plasma-enhanced chemical vapor deposition or the like.

Next, holes 14a are formed in the source insulating film 14 by photolithography or the like. Specifically, a resist having a prescribed pattern is formed by a mask process on the source insulating film 14, and then the source insulating film 14 is etched (by dry etching, for example), forming the holes 14a in the source insulating film 14. The holes 14a are formed through the source insulating film 14 in the thickness direction thereof so as to expose a portion of the source wiring lines 11. The resist is removed as appropriate.

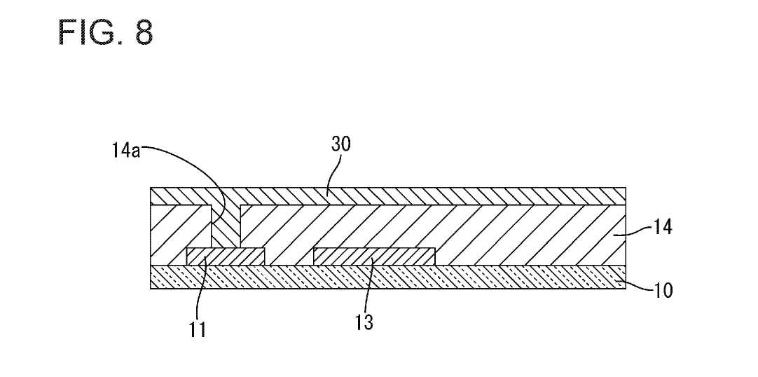

FIG. 8 is a cross-sectional view of a substrate that schematically shows a state in which the oxide semiconductor film 30 is formed on the source insulating film 14. As shown in FIG. 8, the oxide semiconductor film 30 containing indium (In), gallium (Ga), zinc (Zn), and oxygen (O) is formed over the entire source insulating film 14 by sputtering or the like. The oxide semiconductor film 30 is provided for forming the channel region 15, the source electrode portion 16, and the drain electrode portion 17 of each TFT 1. The oxide semiconductor film 30 is formed so as to be connected to the source wiring line 12 through the hole 14a. A portion of the oxide semiconductor film 30 extends in the thickness direction along the taper of the hole 14a, and this portion is connected to the source wiring line 12.

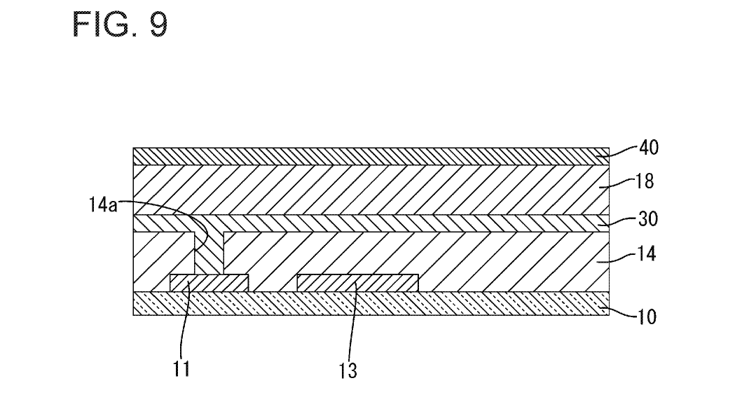

FIG. 9 is a cross-sectional view of a substrate that schematically shows a state in which the gate insulating film 18 and a metal layer 40 (gate metal layer) are formed on the oxide semiconductor film 30. As shown in FIG. 9, the gate insulating film 18 is formed over the entire oxide semiconductor film 30. The gate insulating film 18 is made by layering a silicon oxide film (SiO₂) and a silicon nitride film (SiN_{X}) in this order, for example, and is formed by plasma-enhanced chemical vapor deposition or the like. As shown in FIG. 9, the metal layer 40 is formed on the entire gate insulating film 18. The metal layer 40 is provided for forming the gate electrodes 19 and the gate wiring lines 12, and is formed by sputtering or the like.

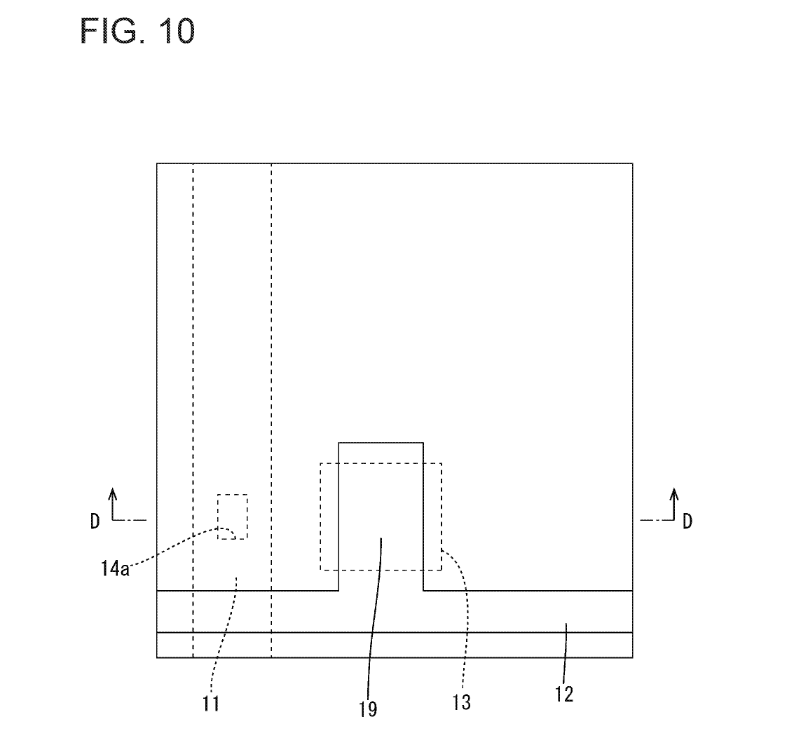

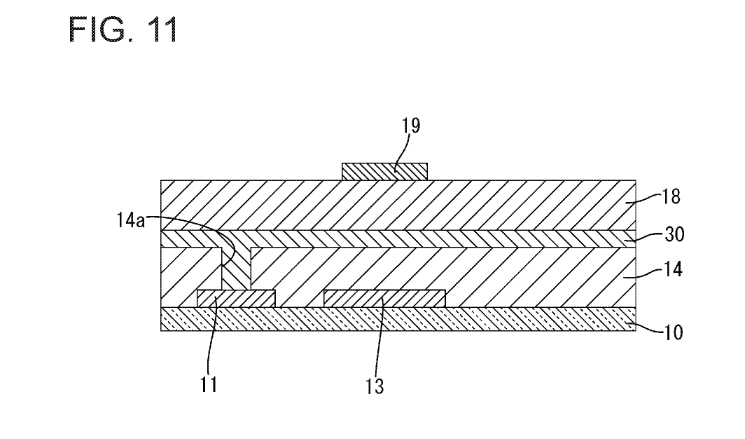

FIG. 10 is a plan view of a substrate that schematically shows a state in which the gate electrode 19 and the gate wiring line 12 have been formed by patterning, and FIG. 11 is a cross-sectional view along the line D-D of FIG. 10. The gate electrodes 19 and the gate wiring lines 12 shown in FIGS. 10 and 11 are formed by patterning the above metal layer 40 (gate metal layer) into a desired shape by photolithography or the like. Specifically, a resist having a prescribed pattern is formed by a mask process on the metal layer 40, and then the metal layer 40 is etched (by wet etching, for example), causing the gate electrodes 19 and the gate wiring lines 12 to be formed as the pattern on the gate insulating film 18.

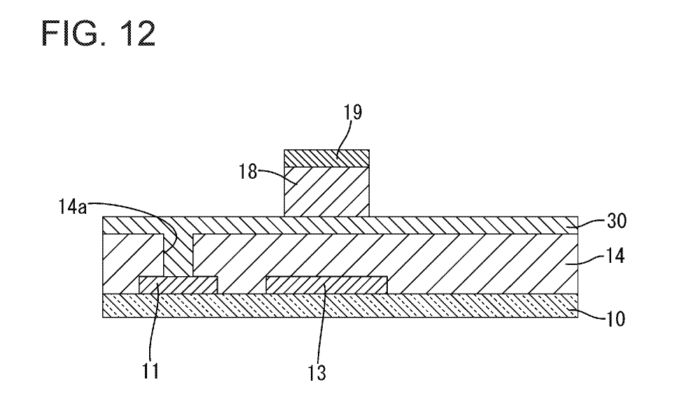

FIG. 12 is a cross-sectional view of a substrate that schematically shows a state in which the gate insulating film 18 has been patterned. The gate insulating film 18 having a pattern is formed by using the same resist used to form the gate electrodes 19 and the gate wiring lines 12 as a mask, and etching (by dry etching, for example) the gate insulating film 18, which had been formed over the entire substrate surface. In this manner, when patterning the gate insulating film 18, it is possible to use the gate electrodes 19 and the gate wiring lines 12 as masks. The resist is removed as appropriate.

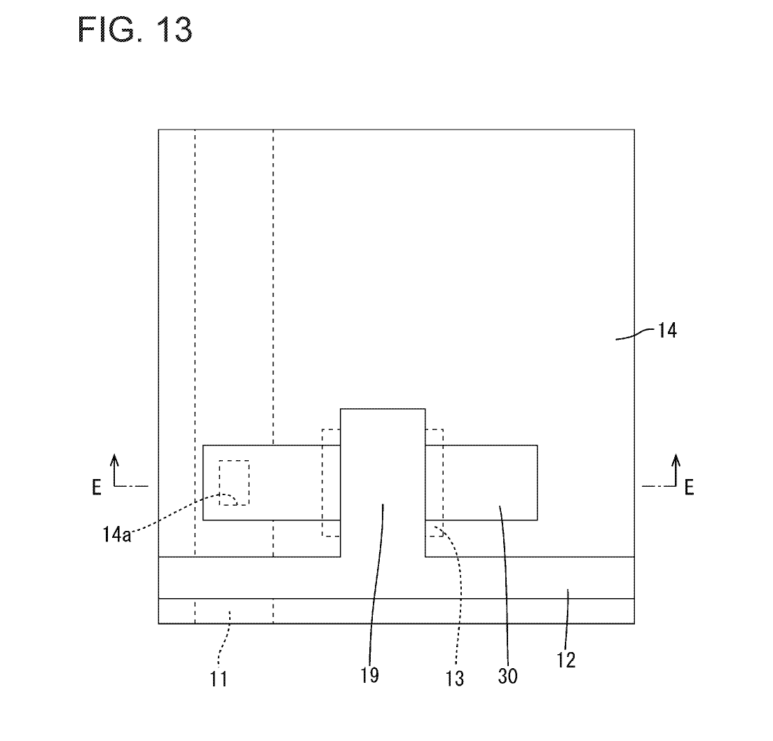

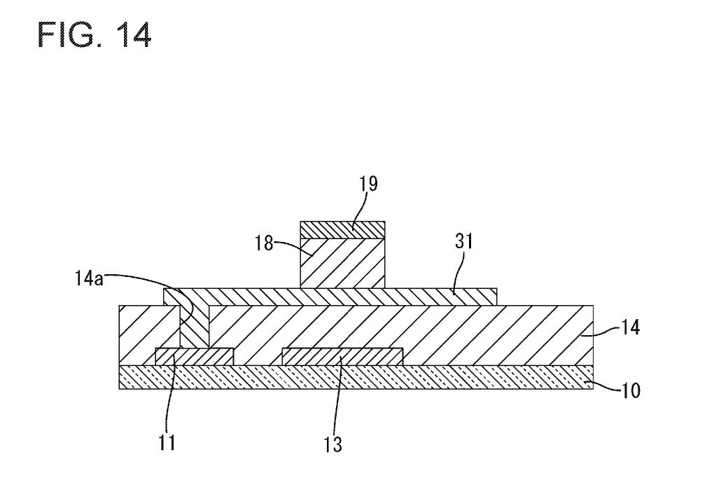

FIG. 13 is a cross-sectional view of a substrate that schematically shows a state in which the oxide semiconductor film 30 has been patterned, and FIG. 14 is a cross-sectional view along the line E-E of FIG. 13. As shown in FIGS. 13 and 14, the oxide semiconductor film 30 formed over the entire substrate surface is patterned into a desired shape by photolithography or the like. Specifically, a resist having a prescribed pattern is formed by a mask process on the oxide semiconductor film 30, and then the oxide semiconductor film 30 is etched (by wet etching, for example), causing the oxide semiconductor film 30 to be formed as the pattern in the form shown in FIGS. 13 and 14. The resist is removed as appropriate.

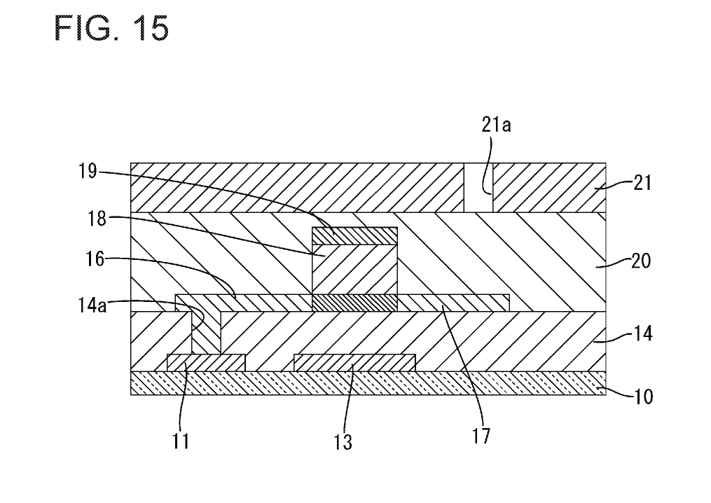

FIG. 15 is a cross-sectional view of a substrate that schematically shows a state in which the first interlayer insulating film 20 and the organic insulating film 21 are formed so as to cover the oxide semiconductor film 30 and the like. The first interlayer insulating film 20 is formed so as to cover all of the gate electrodes 19 while covering portions of the oxide semiconductor film 30 that are not covered by the gate insulating film 18 (that is, portions that would later become the source electrode portions 16 and the drain electrode portions 17). The first interlayer insulating film 20 is made of a silicon nitride film (SiN_{X}), for example. The first interlayer insulating film 20 is made of the silicon nitride film and is formed by plasma-enhanced chemical vapor deposition or the like. As shown in FIG. 15, the organic insulating film 21 is formed by coating a photosensitive resin on the entire first interlayer insulating film 20 by spin coating or the like so as to cover the first interlayer insulating film 20, and then, this coated film is exposed to light through a mask in a prescribed pattern, causing through holes 21a (penetrating holes) to also be formed.

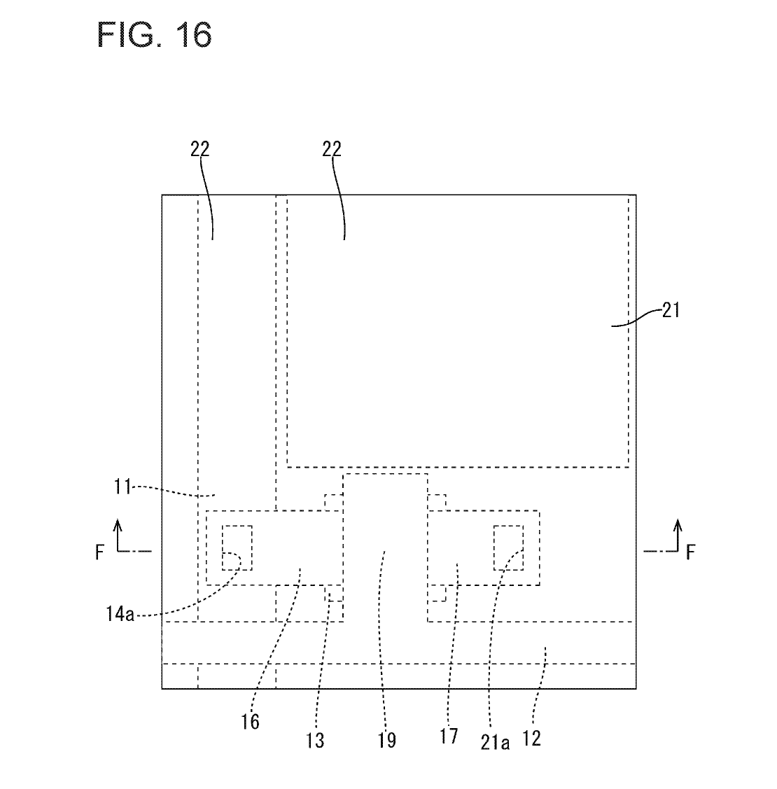

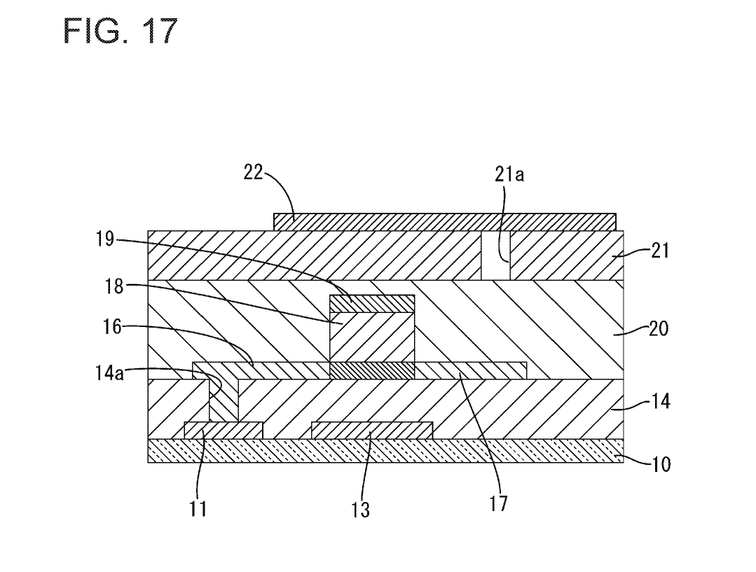

FIG. 16 is a plan view of a substrate that schematically shows a state in which the common electrode 22 has been formed, and FIG. 17 is a cross-sectional view along the line F-F of FIG. 16. After the organic insulating film 21 described above is formed, an electrode material constituting the common electrode 22 is deposited as a layer over the entire organic insulating film 21 by sputtering or the like. The electrode material is a transparent conductive material such as indium tin oxide (ITO) or indium zinc oxide (IZO). Next, the electrode material is patterned by photolithography or the like, causing the common electrode 22 shown in FIGS. 16 and 17 to be formed.

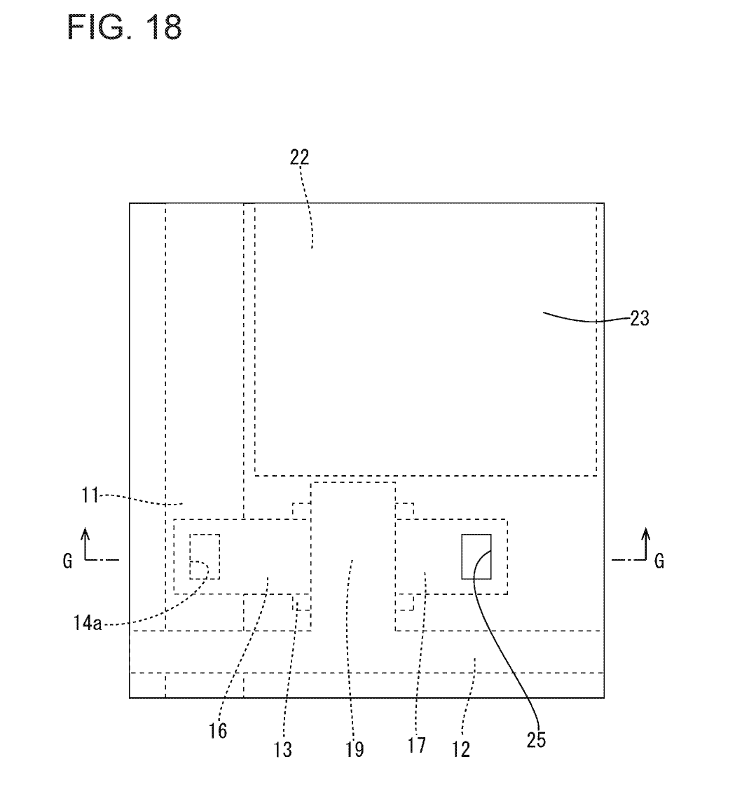

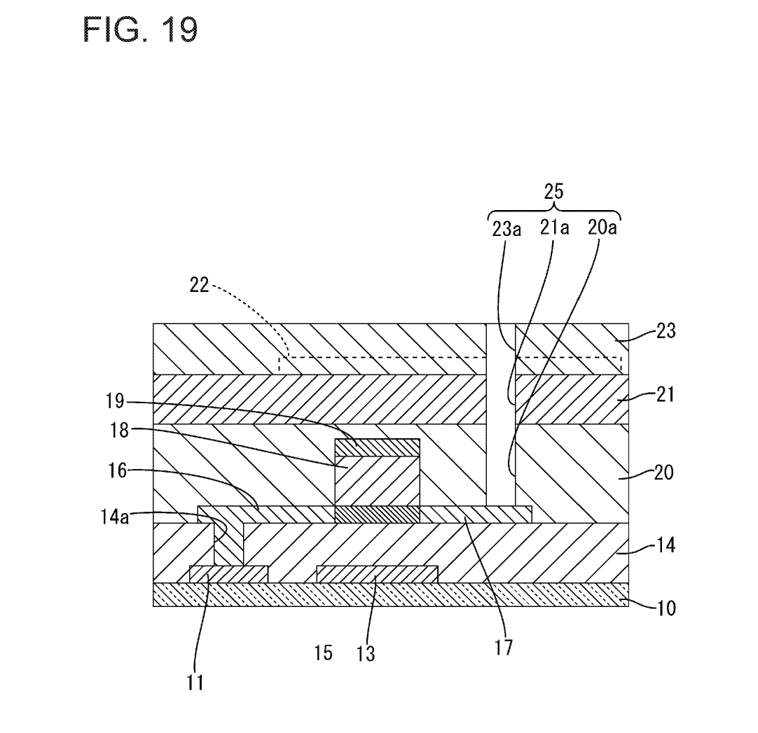

FIG. 18 is a plan view of a substrate that schematically shows a state in which the second interlayer insulating film 23 has been formed, and FIG. 19 is a cross-sectional view along the line G-G of FIG. 18. As shown in FIGS. 18 and 19, the second interlayer insulating film 23 is formed over the entire substrate surface so as to cover the common electrode 22. Similar to the first interlayer insulating film 20, the second interlayer insulating film 23 is made of a silicon nitride (SiN_{X}) by plasma-enhanced chemical vapor deposition or the like, for example.

After the second interlayer insulating film 23 is formed, as shown in FIGS. 18 and 19, the holes 25 (contact holes) are formed through the first interlayer insulating film 20, the organic insulating film 21, and the second interlayer insulating film 23 in the thickness direction thereof. The holes 25 are formed by photolithography or the like. Specifically, a resist having a prescribed pattern is formed on the second interlayer insulating film 23 by a mask process. At this time, a resist pattern for the through holes is formed so as to match the position of the through holes 21a (penetrating holes) in the organic insulating film 21. Then, when the second interlayer insulating film 23 is etched (by dry etching, for example), the holes 25 are formed through the first interlayer insulating film 20 and the second interlayer insulating film 23. The holes 25 are formed through the second interlayer insulating film 23 and the like in the thickness direction thereof so as to expose a portion of the drain electrode portions 17. The resist is removed as appropriate.

Next, an electrode material constituting the pixel electrodes 24 is deposited as a layer over the entire second interlayer insulating film 23 by sputtering or the like. The electrode material is a transparent conductive material such as indium tin oxide (ITO) or indium zinc oxide (IZO). Next, the electrode material is patterned by photolithography or the like, causing the pixel electrodes 24 shown in FIGS. 2 and 3 to be formed. As a result, the TFT array substrate 210 having the cross-sectional configuration shown in FIG. 3 is formed.

By the processes above, the TFT array substrate 210 of the present embodiment is produced. The TFT array substrate 210 is also provided, as appropriate, with components that are not shown here such as an alignment film for controlling the orientation of liquid crystal molecules in the liquid crystal layer, a polarizing plate disposed on the outside of the transparent substrate 10, and optical films.

In this manner, the method of manufacturing the TFT array substrate 210 (semiconductor device) of the present embodiment is provided with such steps, making it possible to provide a top gate TFT array substrate 210 (semiconductor device) in which degradation of the oxide semiconductor film due to light is mitigated.

### Embodiment 2

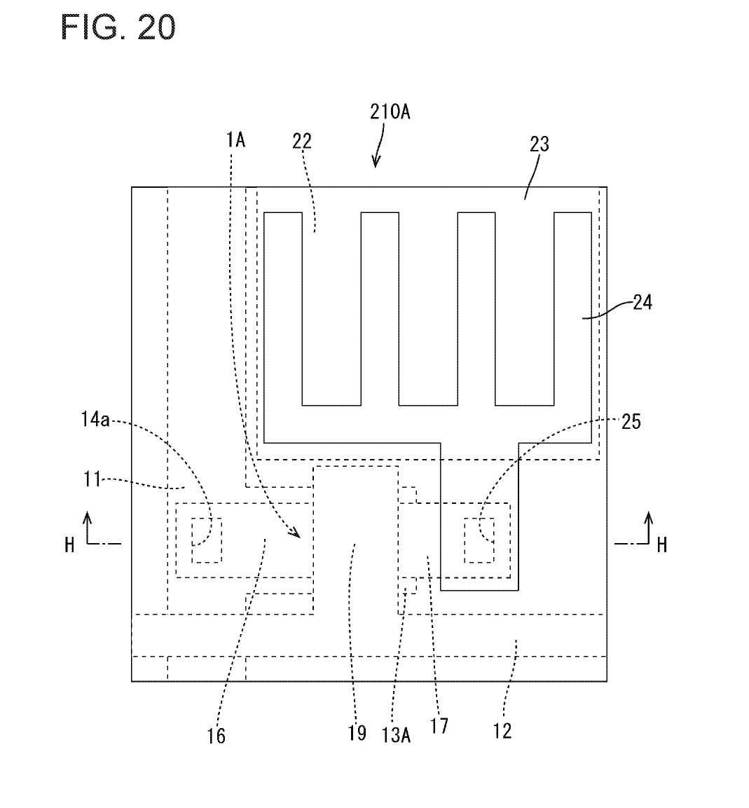

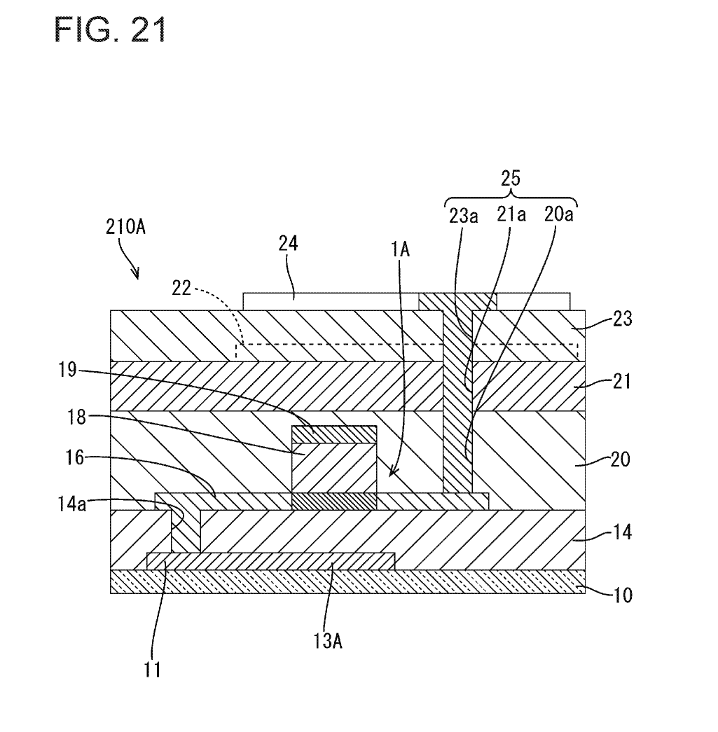

Next, Embodiment 2 of the present invention will be explained below with reference to FIGS. 20 and 21. In each embodiment below, the same components as those in Embodiment 1 are assigned the same reference characters, and descriptions thereof are not repeated. FIG. 20 is a plan view that schematically shows the configuration of a TFT 1A on a TFT array substrate 210A of Embodiment 2, and FIG. 21 is a cross-sectional view along the line H-H of FIG. 20.

In the TFT array substrate 210A of the present embodiment, light-shielding members 13A overlap the channel region 15, similar to Embodiment 1. The light-shielding member 13A is larger than that of Embodiment 1, and is connected to the source wiring line 11. In this manner, the light-shielding members 13A may be provided so as to be connected to the source wiring lines 11 as necessary.

### Embodiment 3

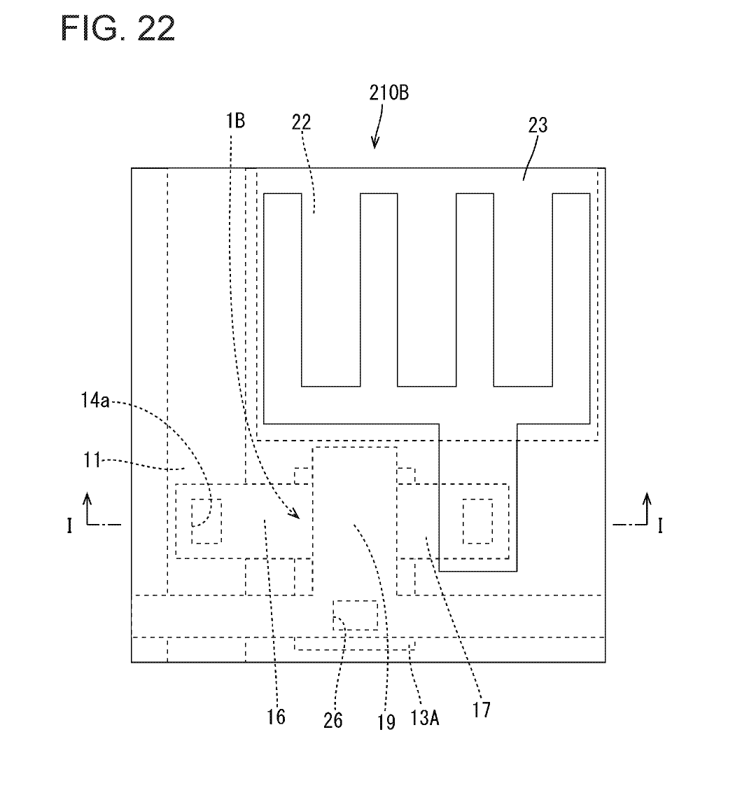

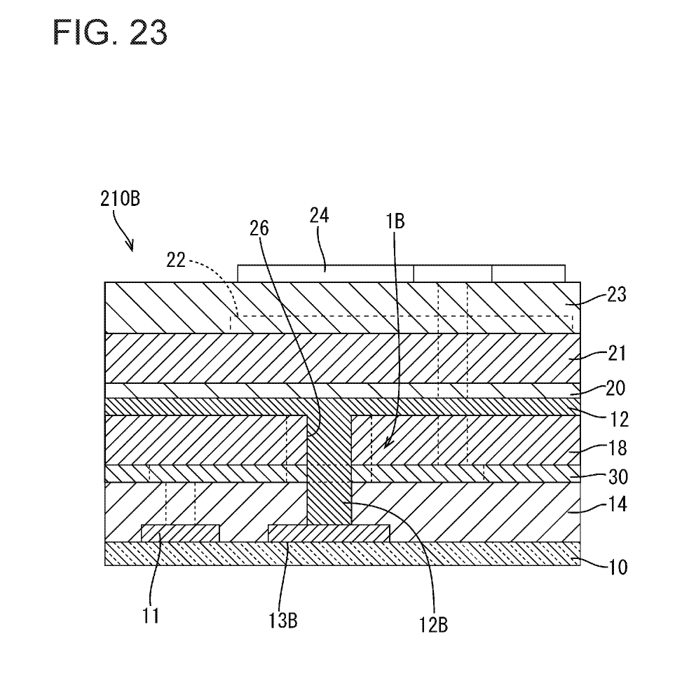

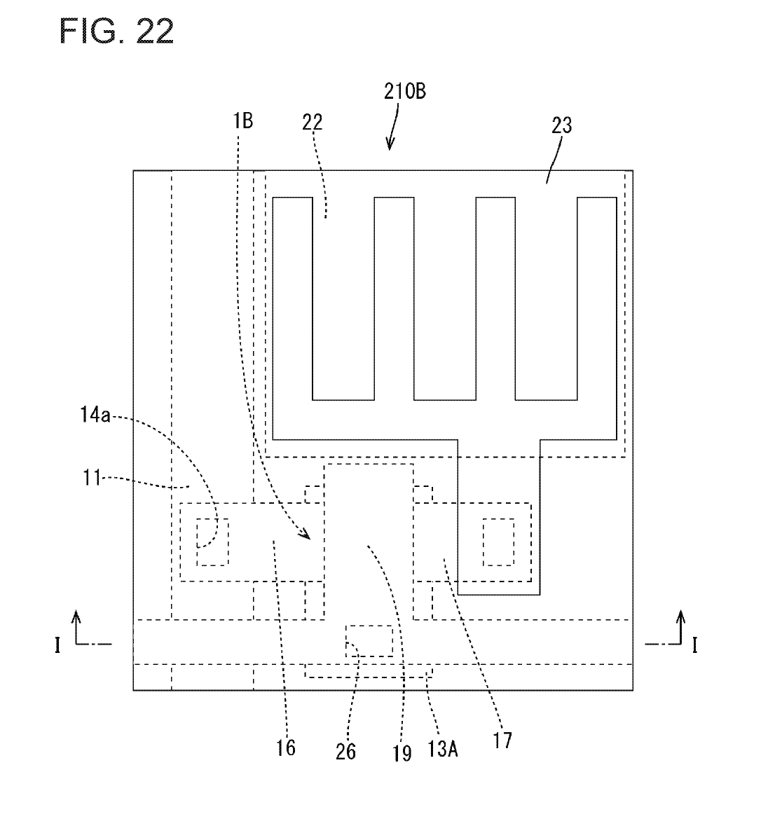

Next, Embodiment 3 of the present invention will be explained below with reference to FIGS. 22 and 23. FIG. 22 is a plan view that schematically shows the configuration of a TFT 1B on a TFT array substrate 210B of Embodiment 3, and FIG. 23 is a cross-sectional view along the line I-I of FIG. 20.

The TFT array substrate 210B of the present embodiment includes light-shielding members 13B having the same shape as in Embodiment 1. However, these light-shielding members 13B are connected to gate wiring lines 12 at the base of the gate electrodes 19, unlike in Embodiment 1. In other words, the light-shielding members 13B are at the same potential as the gate electrodes 19, and the TFTs 1B of the present embodiment have a double gate configuration. Holes 26 (contact holes) are provided so as to penetrate the gate insulating film 18 and the like below the gate wiring lines 12 so as to expose a portion of the light-shielding members 13B, and portions 12B extending below the gate wiring lines 12 are connected to the light-shielding members 13B through the holes 26. In this manner, the light-shielding members 13B may be provided at the same potential as the gate electrodes 19.

### OTHER EMBODIMENTS

The present invention is not limited to the embodiments shown in the drawings and described above, and the following embodiments are also included in the technical scope of the present invention, for example.

(1) In the embodiments above, the oxide semiconductor film contains indium (In), gallium (Ga), zinc (Zn), and oxygen (O), but the oxide semiconductor film is not limited thereto, and may be of any composition that can achieve the object of the present invention. For example, an oxide including at least one element selected from among a group including indium (In), gallium (Ga), aluminum (Al), copper (Cu), zinc (Zn), and tin (Sn) may be used as the semiconductor film material for the semiconductor film.

(2) Each of the TFT array substrates of the embodiments above may further include auxiliary capacitance wiring lines that form an auxiliary capacitance used in order to maintain the voltage applied to the liquid crystal.

(3) In the embodiments above, a TFT array substrate used in a liquid crystal display panel was illustrated as an example of the semiconductor device, but in other embodiments, the semiconductor device may be used in other devices such as organic EL devices, inorganic EL devices, and electrophoretic devices, for example.

(4) In the embodiments above, the TFTs were used as pixel transistors in the pixel area (display region) of the TFT array substrate, but the present invention is not limited thereto, and in other embodiments, the TFTs of the present invention may be used as driver circuit transistors for use in driver circuits such as gate drivers that are formed monolithically in peripheral regions (regions around the display region) of the TFT array substrate, for example. The TFTs for use as driver circuit transistors can be formed on the TFT array substrate at the same time as the manufacturing process for the TFTs 1 in the pixel area illustrated in Embodiment 1 and the like.

Description of Reference Characters

| 1, 1A, 1B | TFT |
|---|---|
| 10 | transparent substrate (substrate) |
| 11 | source wiring line |
| 12 | gate wiring line |
| 13, 13A, 13B | light-shielding member |
| 14 | source insulating film |
| 14a | hole |
| 15 | channel region |
| 16 | source electrode portion |
| 17 | drain electrode portion |
| 18 | gate insulating film |
| 19 | gate electrode |
| 20 | first interlayer insulating film |
| 21 | organic insulating film |
| 22 | common electrode |
| 23 | second interlayer insulating film |
| 24 | pixel electrode |
| 25 | hole |
| 30 | oxide semiconductor film |
| 40 | metal layer (gate metal) |
| 100 | liquid crystal display device |
| 200 | liquid crystal display panel |
| 210 | TFT array substrate (semiconductor device) |
| 220 | opposite substrate |
| 230 | liquid crystal layer |
| 240 | sealing material |
| 300 | backlight device |
| 400 | case |

1: A semiconductor device, comprising:
a substrate;
a source wiring line formed on the substrate;
a light-shielding member formed on the substrate in a same layer as the source wiring line, the light-shielding member being separated from or integrated with the source wiring line;
a source insulating film formed on the substrate so as to cover the source wiring line and the light-shielding member, the source insulating film having a hole penetrating therein in a thickness direction so as to expose a portion of the source wiring line;
an oxide semiconductor film formed on the source insulating film, the oxide semiconductor film having a channel region portion overlapping the light-shielding member, the oxide semiconductor film further including:
a source electrode portion formed by reducing a resistance of a portion of said oxide semiconductor film such that one end of the source electrode portion is connected to the source wiring line through the hole and another end of the source electrode portion is connected to the channel region portion, and
a drain electrode portion formed by reducing a resistance of a portion of said oxide semiconductor film, the drain electrode portion being formed on the source insulating film so as to oppose the source electrode portion with the channel region portion therebetween, the drain electrode portion being connected to the channel region portion;
a gate insulating film formed over the channel region portion so as to overlap the channel region portion; and
a gate electrode formed on the gate insulating film so as to overlap the channel region portion.

2: The semiconductor device according to claim 1, wherein the source wiring line and the light-shielding member are made of a same conductive material.

3: The semiconductor device according to claim 1, wherein the channel region is formed so as not to protrude from edges of the light-shielding member.

4: The semiconductor device according to claim 1, further comprising:
an interlayer insulating film formed on the source insulating film so as to cover the source electrode portion and the drain electrode portion.

5: The semiconductor device according to claim 4, wherein the interlayer insulating film contains as a primary component silicon nitride, and hydrogen contained in the interlayer insulating film reduces the resistance of portions of the oxide semiconductor film corresponding to the source electrode portion and the drain electrode portion.

6: The semiconductor device according to claim 1, wherein the oxide semiconductor film contains indium (In), gallium (Ga), zinc (Zn), and oxygen (O).

7: The semiconductor device according to claim 1, further comprising:
a pixel electrode connected to the drain electrode portion,
wherein the semiconductor device constitutes a pixel transistor in a display region.

8: The semiconductor device according to claim 1, wherein the semiconductor device constitutes a driver circuit transistor formed in a peripheral region around a display region.

9: A display device, comprising:
the semiconductor device according to claim 1,
an opposite substrate disposed opposite the semiconductor device; and
a liquid crystal layer interposed between the semiconductor device and the opposite substrate.

10: The display device according to claim 9, further comprising:
a backlight device that supplies light towards the semiconductor device.

11: A method of manufacturing a semiconductor device, comprising:
forming a conductive film on a substrate;
patterning the conductive film to form, on the substrate, a source wiring line and a light-shielding member in a same layer, the light-shielding member being separated from or integrated with the source wiring line;
forming a source insulating film on the substrate so as to cover the source wiring line and the light-shielding member;
forming a hole through the source insulating film in a thickness direction thereof so as to expose a portion of the source wiring line;
forming an oxide semiconductor film on the source insulating film so as to overlap the light-shielding member while being connected to the source wiring line through the hole;
forming a gate insulating film on the oxide semiconductor film so as to cover a channel region portion of the oxide semiconductor film that overlaps the light-shielding member;
forming a gate electrode on the gate insulating film so as to overlap the channel region portion; and
thereafter, forming an interlayer insulating film on the source insulating film so as to contact portions of the oxide semiconductor film that are not covered by the gate insulating film, the interlayer insulating film causing a resistance of said portions of the oxide semiconductor film to be reduced.

12: The method of manufacturing a semiconductor device according to claim 11, wherein the oxide semiconductor film contains indium (In), gallium (Ga), zinc (Zn), and oxygen (O).

13: The method of manufacturing a semiconductor device according to claim 11, wherein the interlayer insulating film contains a silicon nitride as a primary component and is formed by plasma-enhanced chemical vapor deposition.
